(19) United States
(12) Patent Application Publication
(10) Pub. No.: US 2026/0186020 A1
(43) Pub. Date: Jul. 2, 2026

(54) SEMICONDUCTOR TESTING DEVICE, ATTACHMENT/DETACHMENT SYSTEM FOR SIGNAL TRANSMISSION UNIT, AND ATTACHMENT/DETACHMENT METHOD FOR SIGNAL TRANSMISSION UNIT

(71) Applicant: KABUSHIKI KAISHA NIHON MICRONICS, Tokyo (JP)

(72) Inventors: Hideki IKEUCHI, Tokyo (JP); Furawa ODAGIRI, Tokyo (JP); Shoujirou YAHATA, Tokyo (JP)

(73) Assignee: KABUSHIKI KAISHA NIHON MICRONICS, Tokyo (JP)

(21) Appl. No.: 19/408,138

(22) Filed: Dec. 3, 2025

(30) Foreign Application Priority Data
Dec. 26, 2024 (JP) 2024-230387

(51) Int. Cl. G01R 1/067; G01R 31/28

(52) U.S. Cl. CPC G01R 1/06705; G01R 31/2889

(57) ABSTRACT

A tester includes a performance board unit on which a probe card for testing a semiconductor circuit is mounted, and a main body unit to which the performance board unit is detachably attached, in which the performance board unit has a caster on a side closer to the main body unit, and the main body unit has the caster rail supporting the caster and the lifting unit that raises and lowers the caster rail in an attachment/detachment direction of the performance board unit.

### BACKGROUND OF THE INVENTION

### Field of the Invention

The present invention relates to a semiconductor testing device, an attachment/detachment system for a signal transmission unit, and an attachment/detachment method for a signal transmission unit.

Priority is claimed on Japanese Patent Application No. 2024-230387, filed on Dec. 26, 2024, the content of which is incorporated herein by reference.

### Description of Related Art

Patent Document 1 (Japanese Unexamined Patent Application, First Publication No. 2004-172551) discloses a wafer test system that performs electrical inspection of a plurality of semiconductor chips (dies) formed on a semiconductor wafer. This wafer test system includes a prober that brings a probe into contact with an electrode of a semiconductor chip formed on a wafer, and a tester that has a terminal electrically connected to the probe, operates the semiconductor chip via the terminal, and inspects electrical characteristics of the semiconductor chip by detecting an output signal thereof.

This tester (semiconductor testing device) includes a tester main body, a test head, and a cable connecting the tester main body and the test head.

The test head includes a probe card (device under test) and a performance board electrically connected to a terminal of the probe card. The tester main body includes a board unit that exchanges signals with the test head via the cable, and a power supply unit that supplies power to the board unit.

### SUMMARY OF THE INVENTION

The tester described above has a configuration in which the tester main body and the test head are connected via the cable, but in recent years, there has been a demand for a compact tester in which the tester main body and the test head (performance board) are integrated. Since such a tester houses the above-described units in a single housing, it has been difficult to replace the performance board or substitute the board unit according to specifications of a semiconductor chip, and there has been room for improvement in customizability.

Therefore, the inventors of the present invention have developed a performance board unit (signal transmission unit) in which the performance board is modularized, and conceived a configuration that allows the performance board unit to be detachably attached to the tester main body (main body unit). However, since this performance board unit includes the performance board and a large number of other components, it may become a heavy object weighing, for example, about 80 kg, and thus there has been a problem that attachment and detachment manually is not easy.

The present invention has been made in view of the above-described problems, and an objective thereof is to provide a semiconductor testing device, an attachment/detachment system for a signal transmission unit, and an attachment/detachment method for a signal transmission unit that allow easy attachment and detachment of the signal transmission unit which is a heavy object.

A semiconductor testing device according to one aspect of the present invention includes a signal transmission unit on which a device under test for testing a semiconductor circuit is mounted, and a main body unit to which the signal transmission unit is detachably attached, in which the signal transmission unit includes a caster on a side closer to a main body unit, and the main body unit includes a caster rail supporting the caster and a lifting unit raising and lowering the caster rail in an attachment/detachment direction of the signal transmission unit.

Also, an attachment/detachment system for the signal transmission unit according to one aspect of the present invention includes the semiconductor testing device described above, and a jig including a connecting rail connectable to the caster rail when brought into a raised state by the lifting unit.

Also, an attachment/detachment method for a signal transmission unit according to one aspect of the present invention is an attachment/detachment method for a signal transmission unit of a semiconductor testing device including a signal transmission unit on which a device under test for testing a semiconductor circuit is mounted, and a main body unit to which the signal transmission unit is detachably attached, and the attachment/detachment method includes providing a caster on a side closer to the main body unit of the signal transmission unit, providing the main body unit with a caster rail supporting the caster and a lifting unit raising and lowering the caster rail in an attachment/detachment direction of the signal transmission unit, and sliding the signal transmission unit along the caster rail after the caster rail is raised by the lifting unit.

According to the above-described aspect of the present invention, it is possible to provide a semiconductor testing device, an attachment/detachment system for a signal transmission unit, and an attachment/detachment method for a signal transmission unit that allow easy attachment and detachment of the signal transmission unit which is a heavy object.

### BRIEF DESCRIPTION OF THE DRAWINGS

FIG. 1 is a schematic view of an inspection system including a tester according to one embodiment.

FIG. 2 is a perspective view of the tester according to one embodiment.

FIG. 3 is an exploded perspective view of the tester according to one embodiment.

FIG. 4 is an exploded perspective view of a performance board unit according to one embodiment.

FIG. 5 is a plan view of an underbase unit according to one embodiment with a cover member removed.

FIG. 6A is a view along the arrow VI in FIG. 5 showing a released position of connectors.

FIG. 6B is a view along the arrow VI in FIG. 5 showing a fixed position of connectors.

FIG. 7 is a bottom view of the performance board unit according to one embodiment.

FIG. 8 is a perspective view of the tester according to one embodiment with a part of a unit cover removed.

FIG. 9 is a plan view of a main body unit according to one embodiment.

FIG. 10 is a perspective view illustrating a lifting unit provided in the main body unit according to one embodiment.

FIG. 11 is a flowchart of an attachment/detachment method for the performance board unit according to one embodiment.

FIG. 12 is a schematic view illustrating an initial state of the tester according to one embodiment.

FIG. 13 is an explanatory view for explaining step S2 shown in FIG. 11.

FIG. 14 is an explanatory view for explaining step S3 shown in FIG. 11.

FIG. 15 is a perspective view of region A illustrated in FIG. 14.

FIG. 16 is a perspective view of an attachment/detachment system for the performance board unit including the tester and a jig according to one embodiment.

FIG. 17A is an explanatory view for explaining step S5 in FIG. 11 showing a communication position of openings.

FIG. 17B is an explanatory view for explaining step S5 in FIG. 11 showing a non-communication position of openings.

FIG. 18 is an explanatory view for explaining steps S7 and S8 shown in FIG. 11.

### DETAILED DESCRIPTION OF THE INVENTION

Hereinafter, an embodiment of the present invention will be described on the basis of the drawings.

The embodiment described below is intended to exemplify apparatuses and methods for embodying the technical ideas of this invention, and the embodiment of the invention is not intended to limit materials, shapes, structures, arrangements, and the like of the components to those described below.

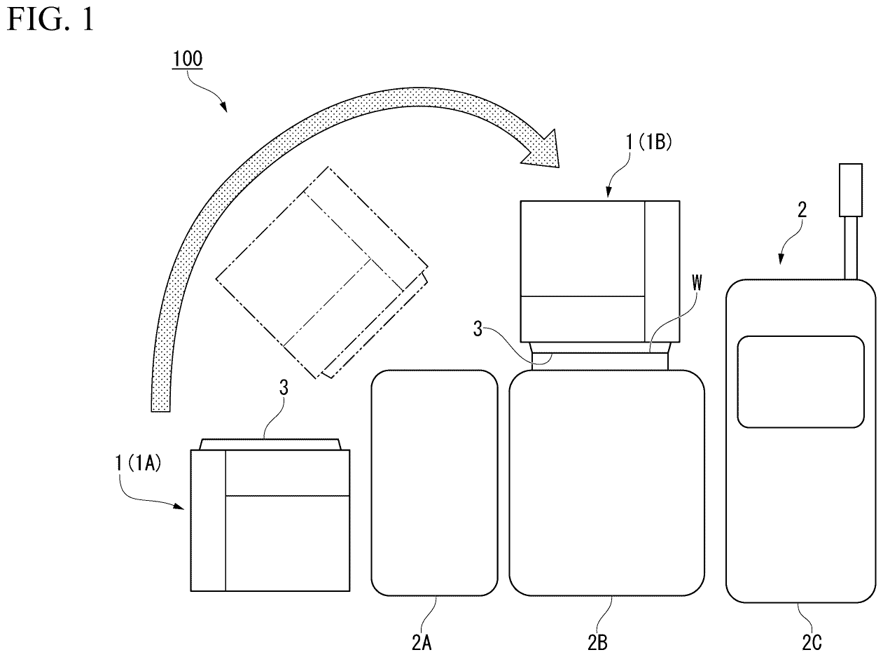

FIG. 1 is a schematic view of an inspection system 100 including a tester 1 according to one embodiment.

The inspection system 100 illustrated in FIG. 1 includes the tester 1 (semiconductor testing device) and a prober 2. The inspection system 100 inspects electrical characteristics of respective semiconductor circuits before a plurality of semiconductor circuits formed on a wafer W are individually diced into chips.

A probe card 3 (device under test) is mounted on the tester 1. The probe card 3 includes a plurality of probes (test needles). The prober 2 brings the plurality of probes provided on the probe card 3 into contact with pads of the plurality of semiconductor circuits formed on the wafer W. The prober 2 includes a tester moving device 2A, a stage device 2B, and a wafer transfer device 2C.

The tester moving device 2A includes a moving mechanism (not illustrated) and moves the tester 1 between a standby position 1A and an inspection position 1B. The stage device 2B supports the wafer W and aligns the tester 1 positioned at the inspection position 1B with the wafer W. The stage device 2B is movable in a planar direction along a horizontal plane and in a vertical direction perpendicular to the horizontal plane, and is also rotatable in a θ direction around a vertical axis. The wafer transfer device 2C transfers the wafer W onto the stage device 2B.

When the inspection is performed, the stage device 2B moves the wafer W and brings pads of the plurality of semiconductor circuits formed on the wafer W into contact with distal end parts of the plurality of probes provided on the tester 1 positioned at the inspection position 1B. In this state, the tester 1 inputs test signals simultaneously to the respective semiconductor circuits via the plurality of probes, and inspects the semiconductor circuits by receiving output signals from the respective semiconductor circuits.

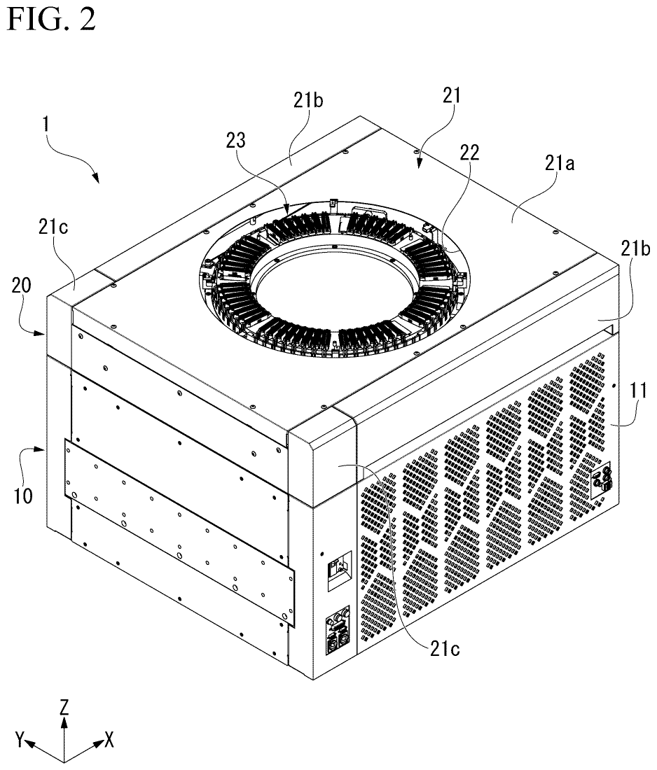

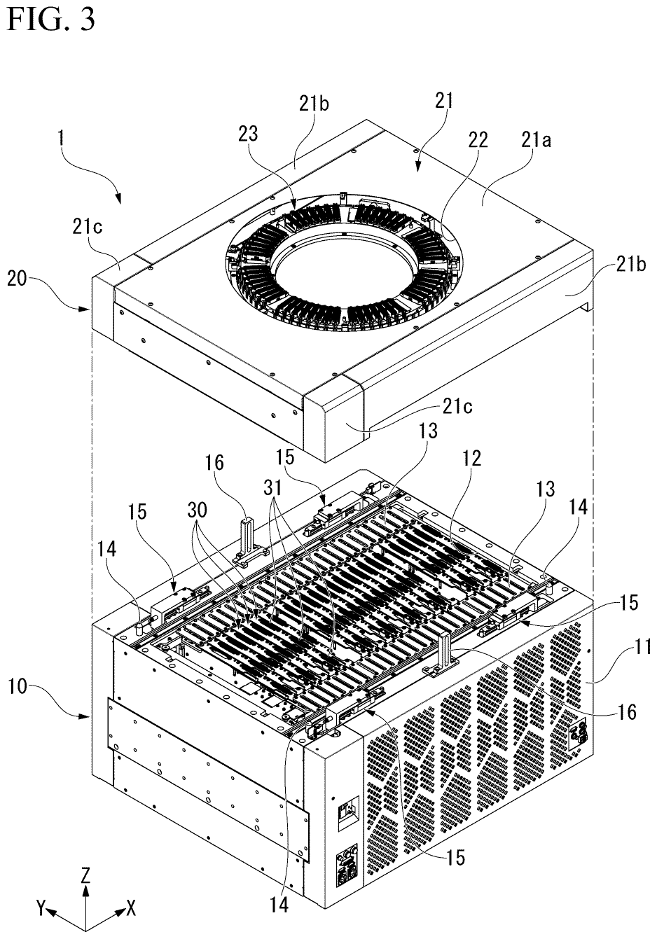

FIG. 2 is a perspective view of the tester 1 according to one embodiment. FIG. 3 is an exploded perspective view of the tester 1 according to one embodiment.

As illustrated in FIG. 2, the tester 1 includes a main body unit 10 and a performance board unit 20 (signal transmission unit). The tester 1 is formed in a rectangular box shape as a whole. The main body unit 10 houses a plurality of board units 30 (see FIG. 3) and power supply units (not illustrated) that supply power to the plurality of board units 30.

Further, in the following description, an XYZ orthogonal coordinate system is set, and positional relationships of respective members may be described with reference to the XYZ orthogonal coordinate system. An X-axis direction is a first linear direction along a horizontal plane, a Y-axis direction is a second linear direction perpendicular to the first linear direction on the horizontal plane, and a Z-axis direction is a vertical direction. Further, in the present embodiment, for convenience of explanation, the main body unit 10 is described as being disposed on a lower side (−Z side), and the performance board unit 20 side as being disposed on an upper side (+Z side), but this positional relationship can be changed depending on an orientation or posture of the tester 1.

As illustrated in FIG. 2, the performance board unit 20 includes a unit cover 21 in which an opening 22 is formed. The unit cover 21 includes a center cover 21a in which an opening 22 is formed, and a first side cover 21b and a second side cover 21c that are separable from the center cover 21a.

The center cover 21a covers a portion of the performance board unit 20 except for side end parts in the Y-axis direction. The first side cover 21b covers portions of the side end parts of the performance board unit 20 in the Y-axis direction except for end parts on the −X side. The second side cover 21c covers portions of the side end parts of the performance board unit 20 in the Y-axis direction that are not covered by the first side cover 21b (end parts on the −X side).

The opening 22 is formed at a center of an upper surface of the center cover 21a. The opening 22 is formed in a circular shape in a plan view from the Z-axis direction. From the opening 22, a device mounting portion 23 on which the probe card 3 (see FIG. 1) can be mounted is exposed. The performance board unit 20 is detachably attached to an upper part of the main body unit 10. An attachment/detachment direction of the performance board unit 20 is the Z-axis direction.

As illustrated in FIG. 3, the main body unit 10 includes a rectangular box-shaped housing 11 that opens upward. An accommodating portion 12 that is open upward and accommodates the plurality of board units 30 is formed inside the housing 11. The plurality of board units 30 are accommodated in the accommodating portion 12 with gaps between them in the X-axis direction. The plurality of board units 30 generate test signals to be input to the plurality of semiconductor circuits formed on the wafer W, and receive and inspect output signals from the respective semiconductor circuits. The plurality of board units 30 can be increased or decreased in number, or replaced, in accordance with specifications of the semiconductor circuits formed on the wafer W.

A plurality of (two or three) first connectors 31 are provided on an upper part of each of the plurality of board units 30. The plurality of first connectors 31 are connected to a lower surface of the performance board unit 20. A board holder 13 that protrudes horizontally toward the accommodating portion 12 and restricts upward removal of the plurality of board units 30 is detachably attached to an upper end opening edge of the housing 11.

Also, a positioning pin 14 for positioning the performance board unit 20, a clamp device 15 for clamping the performance board unit 20, and a lock bracket 16 for locking the performance board unit 20 are provided at the upper end opening edge of the housing 11. The positioning pin 14 is provided at positions corresponding to three of four corner portions of the housing 11 in a plan view. Thereby, the performance board unit 20 can be prevented from being attached to the main body unit 10 in an incorrect orientation.

A total of four clamp devices 15 are provided, two on each of two sides of the upper end opening edge of the housing 11 extending in the X-axis direction. Of the four clamp devices 15, three cause clamp pins to advance and retract in the X-axis direction toward the positioning pins 14. The remaining one of the clamp devices 15 causes a clamp pin to advance and retract in the X-axis direction toward a corner portion of the housing 11 in which no positioning pin 14 is provided. The clamp device 15 is electrically driven and can be switched between a clamped state and an unclamped state with the performance board unit 20. A pair of lock brackets 16, each having a long hole extending in the Z-axis direction, are provided with the accommodating portion 12 interposed therebetween in the Y-axis direction.

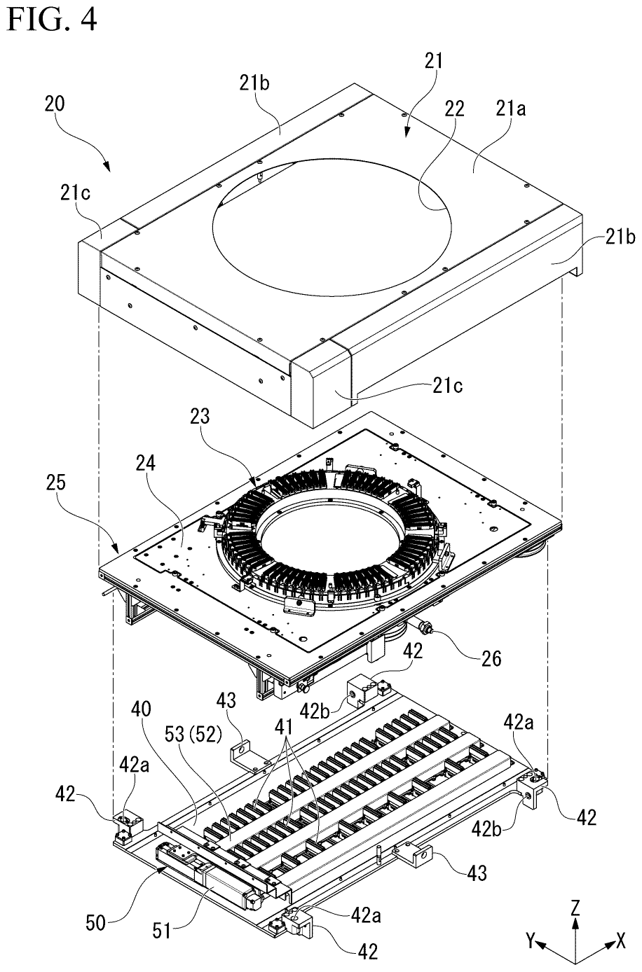

FIG. 4 is an exploded perspective view of the performance board unit 20 according to one embodiment. As illustrated in FIG. 4, the performance board unit 20 includes a performance board 24 on which the device mounting portion 23 is provided. The performance board 24 is interposed between the probe card 3 (see FIG. 1) and the plurality of board units 30 (see FIG. 3), and transmits signals required for testing.

The device mounting portion 23 is provided on an upper surface of the performance board 24. A lock plunger 26 that can be fitted into the lock bracket 16 (see FIG. 3) is provided on a lower surface of the performance board 24. A pair of lock plungers 26 are provided in correspondence with the lock brackets 16. The lock plunger 26 is switchable between an engaged state and a disengaged state with respect to the lock bracket 16. The performance board 24 is attached to an underbase unit 40 via a frame unit 25.

The underbase unit 40 forms a lower surface of the performance board unit 20. A plurality of second connectors 41 are provided in the underbase unit 40. The plurality of second connectors 41 are provided in a number and disposition corresponding to the plurality of first connectors 31 illustrated in FIG. 3. The plurality of second connectors 41 are connected to the plurality of first connectors 31 in the Z-axis direction.

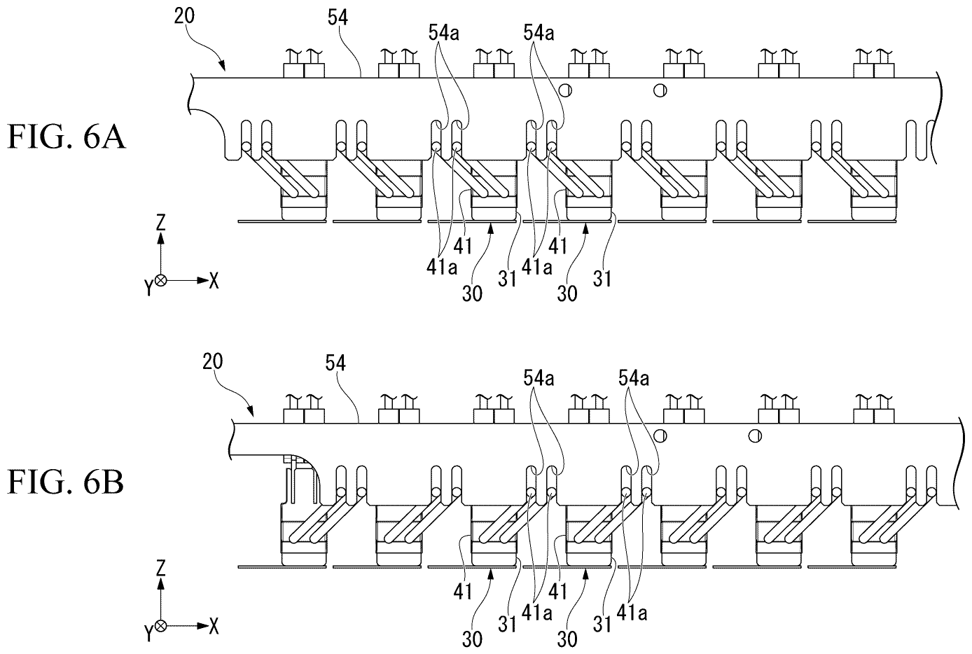

The first connector 31 and the second connector 41 are, for example, a zero insertion force (ZIF) connector. A lock lever 41a (see FIGS. 6A and 6B, which will be described later) is provided in the second connector 41. The second connector 41 can be switched, by operating the lock lever 41a, between a fixed state in which it is fixed to the first connector 31 and a released state in which the fixation to the first connector 31 is released. Further, as long as the fixed state and the released state can be switched by moving the lock lever 41a, the first connector 31 and the second connector 41 need not be ZIF connectors.

Returning to FIG. 4, the underbase unit 40 is formed in a rectangular plate shape in a plan view. An engagement piece 42 is attached to each of four corner portions of the underbase unit 40. The engagement piece 42, corresponding to the configuration on the main body unit 10, has a positioning hole 42a into which the positioning pin 14 can be inserted in the Z-axis direction, and a clamp hole 42b into which the clamp pin of the clamp device 15 can be inserted in the X-axis direction.

Mount pieces 43 for mounting the lock plungers 26 are attached at central portions of two sides of the underbase unit 40 extending in the X-axis direction. A unit attachment/detachment mechanism 50 is provided on an upper surface of the underbase unit 40. The unit attachment/detachment mechanism 50 includes a motor unit 51 and a lock lever interlocking mechanism 52. The lock lever interlocking mechanism 52 is covered by a cover member 53.

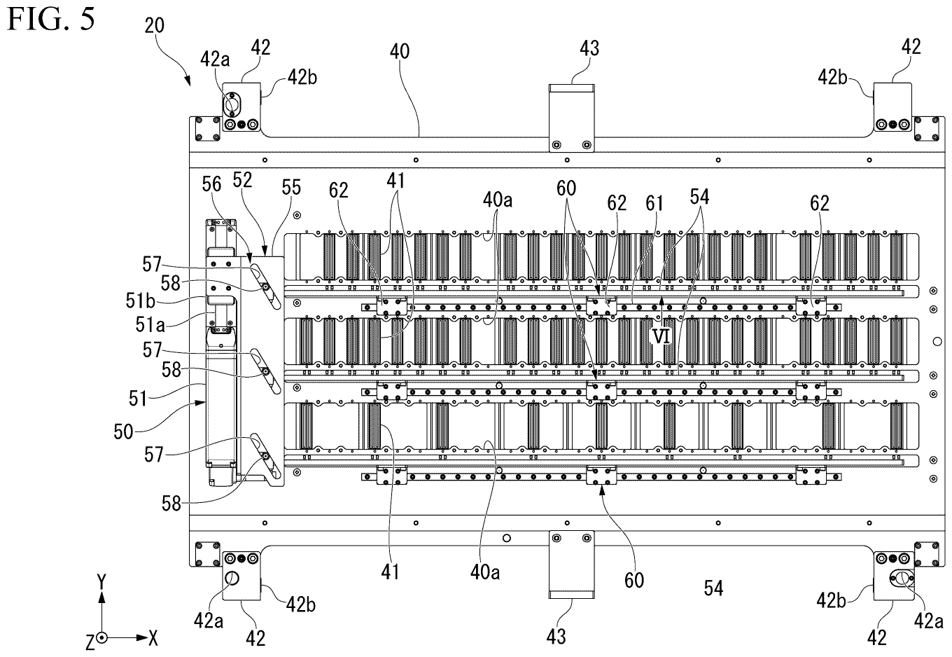

FIG. 5 is a plan view of the underbase unit 40 according to one embodiment with the cover member 53 removed. FIGS. 6A and 6B is a view along the arrow VI illustrated in FIG. 5.

As illustrated in FIG. 5, a plurality of (three) attachment holes 40a are formed in the underbase unit 40. The plurality of second connectors 41 are attached to the plurality of attachment holes 40a. The plurality of attachment holes 40a extend parallel to the X-axis direction at intervals in the Y-axis direction. The plurality of second connectors 41 form a row in the X-axis direction by being attached to the respective attachment holes 40a.

The motor unit 51 is disposed on the upper surface of the underbase unit 40 on a −X side of the plurality of attachment holes 40a. The motor unit 51 includes a ball screw 51a extending in the Y-axis direction, and a nut 51b that moves in the Y-axis direction along the ball screw 51a as the ball screw 51a rotates.

The lock lever interlocking mechanism 52 includes a plurality of (three) engagement members 54 provided to be movable in the X-axis direction (first linear direction) in a plan view, a moving member 55 provided to be movable in the Y-axis direction (second linear direction) that is orthogonal to the X-axis direction in a plan view, and a motion conversion mechanism 56 converting movement of the moving member 55 in the Y-axis direction into movement of the engagement member 54 in the X-axis direction.

As illustrated in FIGS. 6A and 6B, the engagement member 54 has a comb-tooth shape and includes a plurality of engagement grooves 54a that engage with a plurality of lock levers 41a. The plurality of engagement grooves 54a are open downward. As illustrated in FIG. 5, the engagement member 54 is disposed on the −Y side of the attachment hole 40a, extends linearly in the X-axis direction in which the second connectors 41 form a row, and engages with the lock lever 41a of each second connector 41. The engagement member 54 is connected to a linear guide 60.

The linear guide 60 includes a rail 61 extending in the X-axis direction and a plurality of slide blocks 62 that move along the rail 61. The engagement member 54 is attached to the plurality of slide blocks 62 and is movable in the X-axis direction. The engagement member 54 moves in the X-axis direction to move the lock lever 41a between a fixed position (see FIG. 6B) in which the plurality of second connectors 41 and the plurality of first connectors 31 are fixed and a released position (see FIG. 6A) in which the fixation between the plurality of second connectors 41 and the plurality of first connectors 31 is released.

As illustrated in FIG. 5, the moving member 55 is attached to the nut 51b of the motor unit 51 and is movable in the Y-axis direction. The moving member 55 is formed in a plate shape that is long in the Y-axis direction in a plan view. The motion conversion mechanism 56 includes a long hole 57 provided in the moving member 55 and extending in an oblique direction intersecting the X-axis direction and the Y-axis direction in a plan view, and a cam follower 58 provided in the engagement member 54 and movable along an inner wall of the long hole 57.

Three long holes 57 are formed corresponding to the three engagement members 54. The three long holes 57 extend parallel to each other in an oblique direction that is inclined toward the −Y side as proceeding toward the +X side in a plan view. The cam follower 58 is attached to an end part of each engagement member 54 on the −X side. The cam follower 58 includes a wheel portion that is rotatable around a shaft extending in the Z-axis direction. An outer diameter of the cam follower 58 is slightly smaller than a width of the long hole 57 and is capable of rolling along an inner wall surface of the long hole 57.

For example, when the moving member 55 moves to the −Y side, the cam follower 58 rolls on the inner wall surface of the long hole 57 and moves to one end part of the long hole 57 on the −X side. When the cam follower 58 moves to the one end part of the long hole 57, the engagement member 54 moves to the −X side together with the cam follower 58, and as a result, the lock lever 41a moves to the released position as illustrated in FIG. 6a.

Also, when the moving member 55 moves to the +Y side, the cam follower 58 rolls along the inner wall surface of the long hole 57 and moves to the other end part on the +X side of the long hole 57. When the cam follower 58 moves to the other end part of the long hole 57, the engagement member 54 moves to the +X side together with the cam follower 58, and as a result, the lock lever 41a moves to the fixed position as illustrated in FIG. 6B.

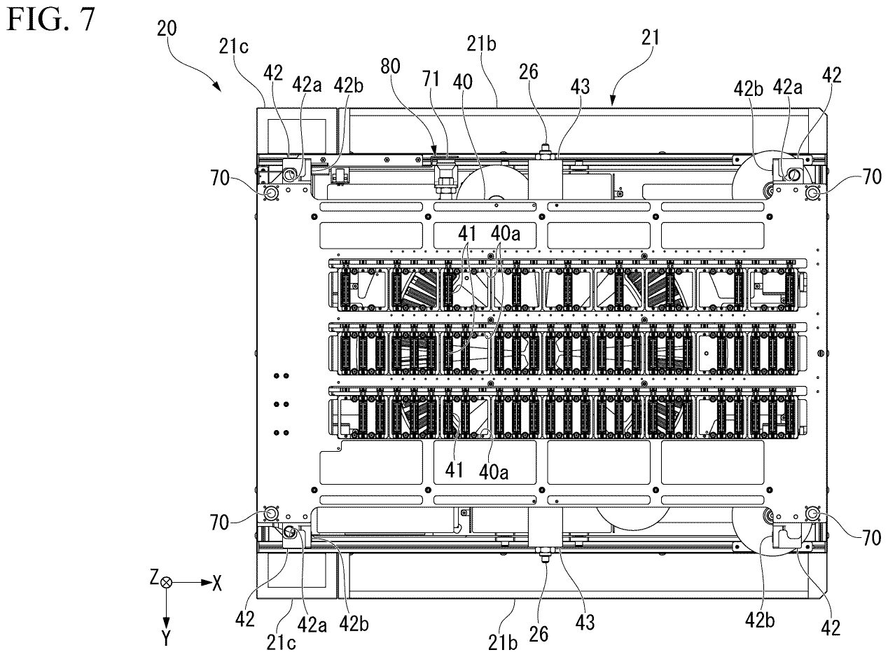

FIG. 7 is a bottom view of the performance board unit 20 according to one embodiment.

As illustrated in FIG. 7, a caster 70 is provided on the bottom side (main body unit 10 side) of the performance board unit 20. The caster 70 is provided at positions corresponding to four corner portions of a lower surface of the underbase unit 40. The caster 70 is, for example, a ball caster, but may also be a wheel, a roller, or the like.

An operation unit 71 for releasing engagement of the lock plunger 26 with the lock bracket 16 is provided at a side end part on the −Y side of the performance board unit 20. The operation unit 71 is, for example, a knob operable by pulling, and is connected to the lock plunger 26 via a wire or the like (not illustrated). A spring pin of the lock plunger 26 can be retracted by pulling the operation unit 71, and thereby the engagement of the lock plunger 26 with the lock bracket 16 can be released. The operation unit 71 is normally inoperable by an interlock portion 80 to be described later.

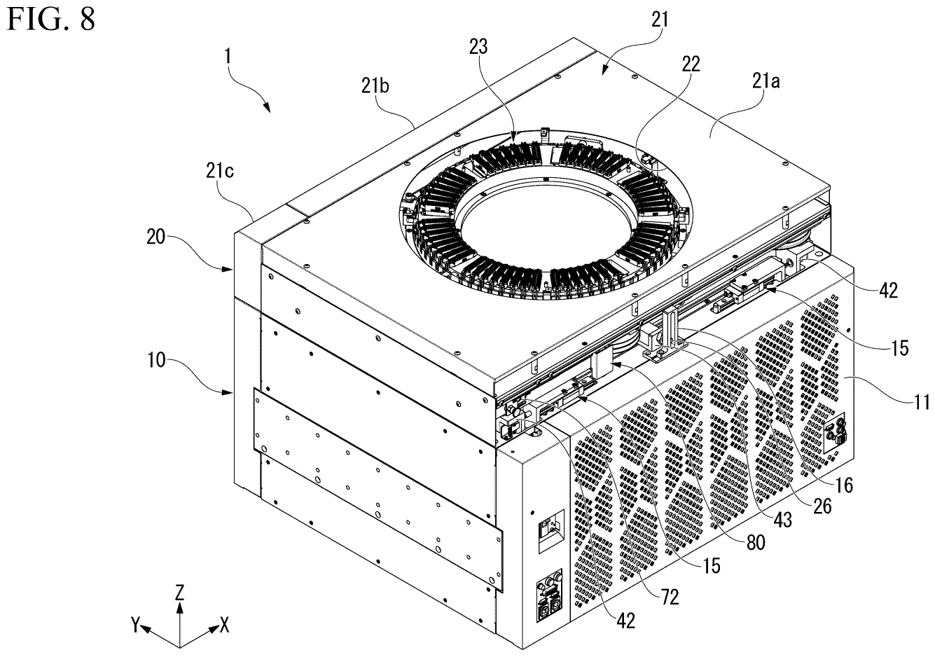

FIG. 8 is a perspective view of the tester 1 according to one embodiment with a part of the unit cover 21 removed.

As illustrated in FIG. 8, the performance board unit 20 has a connector portion 72 disposed at an end part on the −X side of the side end part facing the −Y side. The connector portion 72 can be exposed to the outside by removing the second side cover 21c.

The connector portion 72 is connected to the main body unit 10 in a direction (Y-axis direction) other than the attachment/detachment direction (Z-axis direction) of the performance board unit 20. The main body unit 10 includes a cable (not illustrated) passing through the housing 11, and an external connector (not illustrated) provided at an end part of the cable is connected to the connector portion 72 in the Y-axis direction. The motor unit 51 illustrated in FIGS. 4 and 5 is configured to receive power supply from the main body unit 10 via the connector portion 72 to operate the lock lever interlocking mechanism 52.

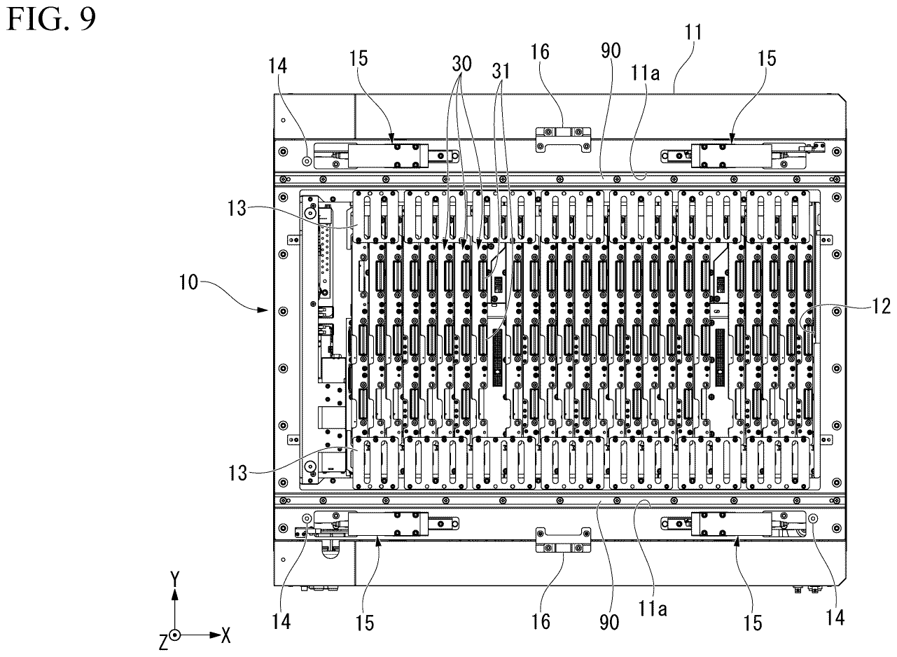

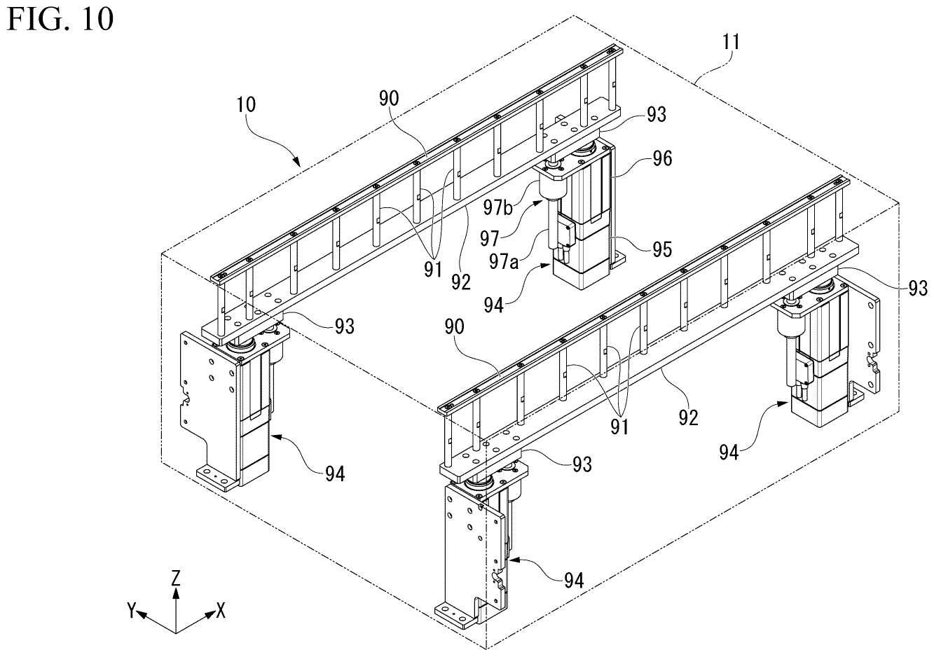

FIG. 9 is a plan view of the main body unit 10 according to one embodiment. FIG. 10 is a perspective view illustrating a lifting unit 94 provided in the main body unit 10 according to one embodiment.

As illustrated in FIG. 9, the main body unit 10 includes a caster rail 90. Two caster rails 90 are provided in total, one on each of two sides of an upper end opening edge of the housing 11 extending in the X-axis direction. The caster rails 90 support the casters 70 (see FIG. 7) of the performance board unit 20 from below.

The caster rails 90 are provided as a pair on the upper end opening edge of the housing 11 with the accommodating portion 12 interposed therebetween in the Y-axis direction. The pair of caster rails 90 extend parallel to the X-axis direction. The pair of caster rails 90 are disposed, in a plan view, closer to the accommodating portion 12 than the positioning pin 14, the clamp device 15, and the lock bracket 16 described above. A rail accommodating groove 11a for accommodating the caster rail 90 is formed on the upper end opening edge of the housing 11. The caster rail 90 accommodated in the rail accommodating groove 11a is flush with an upper surface of the main body unit 10.

As illustrated in FIG. 10, the caster rails 90 are supported at upper ends of a plurality of support columns 91 extending in the Z-axis direction. The plurality of support columns 91 are disposed at intervals in the X-axis direction. Further, a plurality of through holes (not illustrated) through which the plurality of support columns 91 can pass in the Z-axis direction are formed at a groove bottom of the rail accommodating groove 11a illustrated in FIG. 9. As illustrated in FIG. 10, lower ends of the plurality of support columns 91 are attached to an attachment plate 92 extending in the X-axis direction. An engagement plate 93 with which the lifting unit 94 engages is attached to lower surfaces of both end parts of the attachment plate 92 in the X-axis direction.

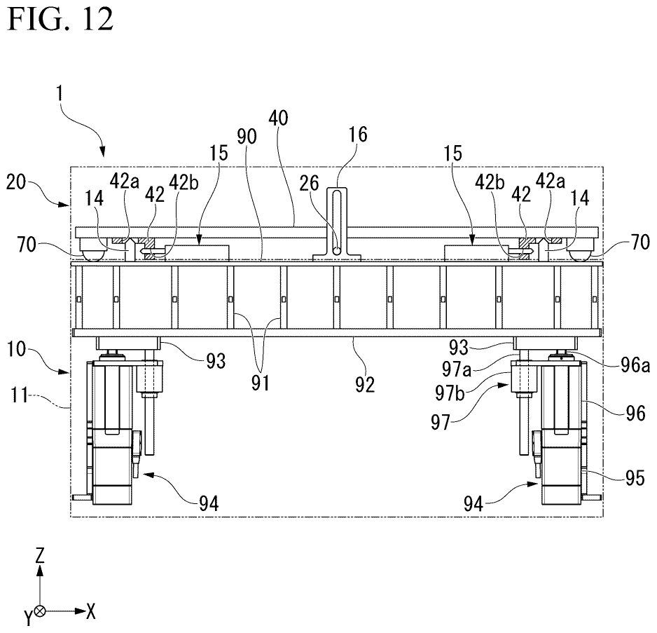

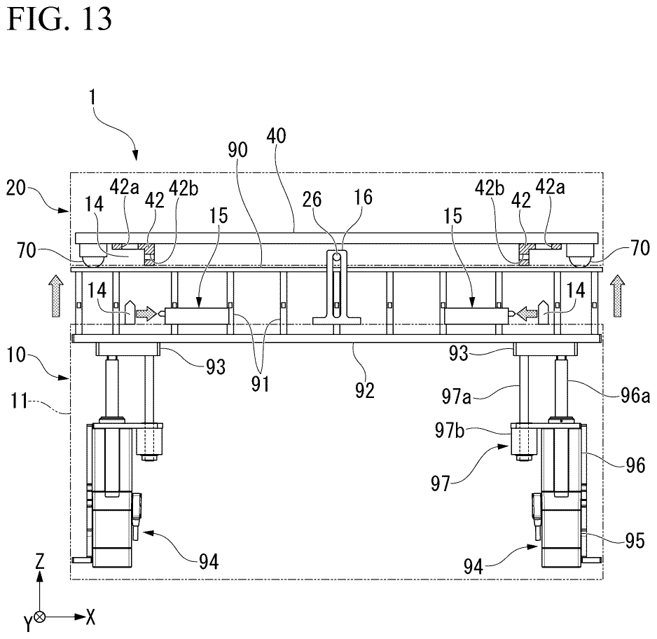

One caster rail 90 can be raised and lowered in the Z-axis direction by two lifting units 94. That is, four lifting units 94 are provided in the main body unit 10. The lifting unit 94 includes a motor unit 95, an extensible portion 96, and a guide portion 97. The motor unit 95 is connected to the extensible portion 96. The extensible portion 96 includes an extensible rod 96a (see FIGS. 12 and 13 to be described later) that extends and contracts in the Z-axis direction due to rotation of the motor unit 95.

The extensible portion 96 includes a mechanism (for example, a ball screw or the like) that converts rotation of the motor unit 95 into movement of the extensible rod 96a in the Z-axis direction. An upper end part of the extensible rod 96a engages with the engagement plate 93. The guide portion 97 includes a guide rod 97a fixed to the engagement plate 93, and a guide cylinder 97b fixed to the extensible portion 96 and slidably engaged with the guide rod 97a in the Z-axis direction. The guide portion 97 restricts an inclination or the like of the extensible rod 96a and improves an operation accuracy of the lifting unit 94 in the Z-axis direction.

Next, an attachment/detachment method for the performance board unit 20 (attachment/detachment method for the signal transmission unit) with respect to the tester 1 having the above-described configuration will be described.

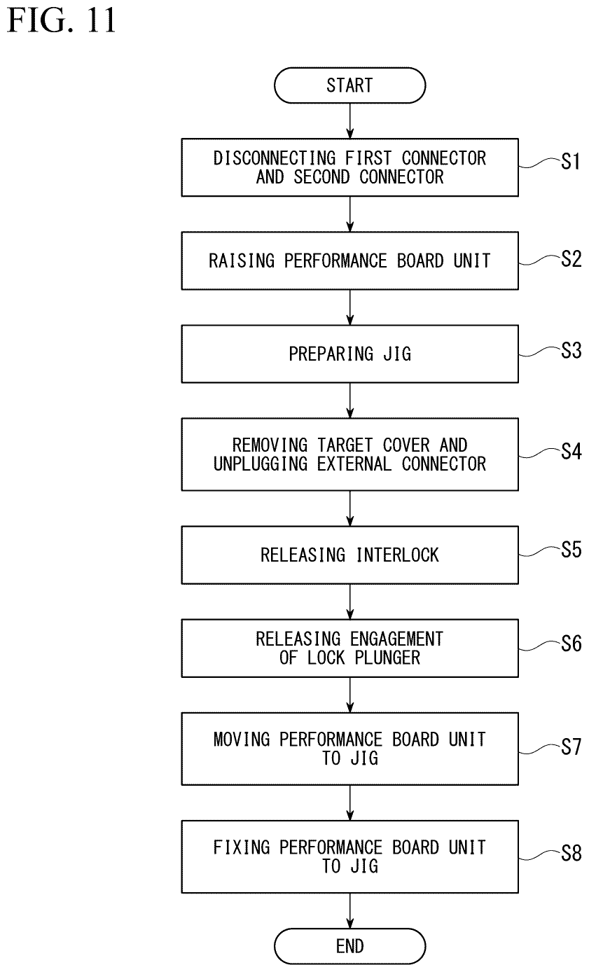

FIG. 11 is a flowchart of an attachment/detachment method for the performance board unit 20 according to one embodiment.

As shown in FIG. 11, the present method includes step S1 of disconnecting the first connector 31 and the second connector 41, step S2 of raising the performance board unit 20, step S3 of preparing a jig 201, step S4 of removing a target cover and unplugging the external connector, step S5 of releasing the interlock, step S6 of releasing engagement of the lock plunger 26, step S7 of moving the performance board unit 20 to the jig 201, and step S8 of fixing the performance board unit 20 to the jig 201. Thereby, the performance board unit 20 can be removed from the main body unit 10.

Hereinafter, the present method will be described in detail with reference to FIGS. 12 to 18. Further, when the performance board unit 20 is attached to the main body unit 10, the above-described steps are followed in reverse order.

FIG. 12 is a schematic view illustrating an initial state of the tester 1 according to one embodiment. Further, in FIG. 12, for improved visibility, only components related to attachment and detachment of the performance board unit 20 are illustrated. The same applies to FIGS. 13, 14, and 18 to be described later. As illustrated in FIG. 12, in the initial state, the performance board unit 20 is attached to the main body unit 10 with the caster 70 placed on the caster rail 90. The caster rail 90 is lowered to a position at which it is accommodated in the rail accommodating groove 11a illustrated in FIG. 9.

The positioning pin 14 of the main body unit 10 is inserted in the Z-axis direction into the positioning hole 42a of the engagement piece 42 of the performance board unit 20. Also, the clamp pin of the clamp device 15 of the main body unit 10 is inserted in the X-axis direction into the clamp hole 42b of the engagement piece 42. Also, the lock plunger 26 of the performance board unit 20 engages with a lower end part of the long hole in the lock bracket 16 of the main body unit 10.

In step S1, from this state, the motor unit 51 illustrated in FIG. 5 is driven to move the moving member 55 to the −Y side. When the moving member 55 moves to the −Y side, the cam follower 58 moves to the −X side along the long hole 57. When the cam follower 58 moves to the −X side, the engagement member 54 moves to the −X side together with the cam follower 58, and the lock lever 41a engaged with the engagement member 54 moves (rotates) to the released position as illustrated in FIG. 6A. Thereby, the fixation between the first connector 31 and the second connector 41 is released.

FIG. 13 is an explanatory view for explaining step S2 shown in FIG. 11.

After the first connector 31 and the second connector 41 have been disconnected, the clamp device 15 is driven to pull out the clamp pin from the clamp hole 42b of the engagement piece 42 as illustrated in FIG. 13. Next, the lifting unit 94 is driven to raise the caster rail 90.

When the caster rail 90 is raised, the performance board unit 20 rises together with the caster rail 90, and the positioning pin 14 is pulled out from the positioning hole 42a of the engagement piece 42. At this time, although the lock plunger 26 rises along the long hole of the lock bracket 16, since it is engaged with an upper end part of the long hole, movement of the performance board unit 20 in the X-axis direction along the caster rail 90 is restricted.

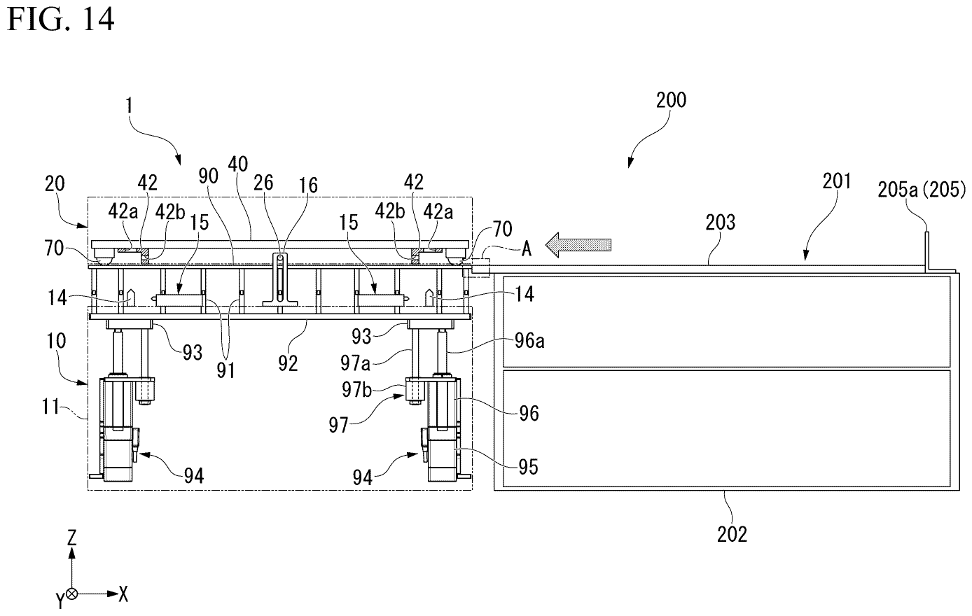

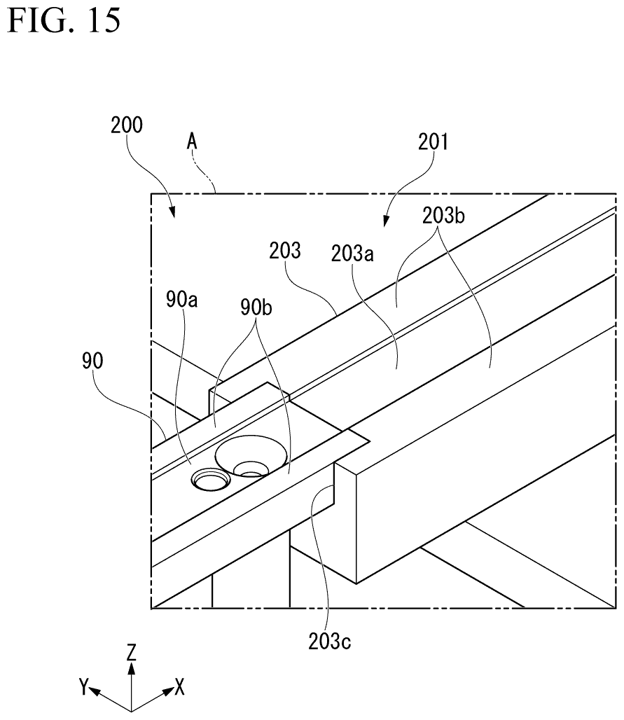

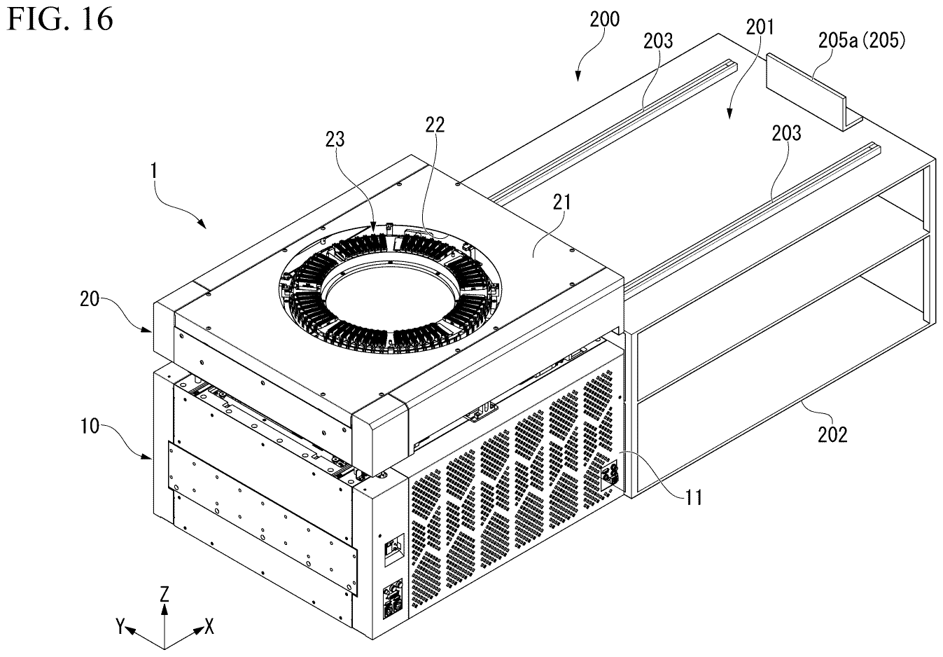

FIG. 14 is an explanatory view for explaining step S3 shown in FIG. 11. FIG. 15 is a perspective view of region A illustrated in FIG. 14. FIG. 16 is a perspective view of an attachment/detachment system 200 for the performance board unit 20 (attachment/detachment system for the signal transmission unit) including the tester 1 and the jig 201 according to one embodiment.

After the performance board unit 20 has been raised, as illustrated in FIG. 14, the jig 201 is disposed on a side of the tester 1, and a connecting rail 203 of the jig 201 is connected to the caster rail 90 that is in a raised state by the lifting unit 94.

As illustrated in FIG. 16, the jig 201 includes a jig main body 202, a pair of connecting rails 203 provided on an upper surface of the jig main body 202, and a stopper 205a provided on the upper surface of the jig main body 202 to restrict falling of the performance board unit 20. The jig main body 202 is, for example, a carriage having a rectangular shape in a plan view, and the pair of connecting rails 203 and the stopper 205a are attached to the upper surface thereof.

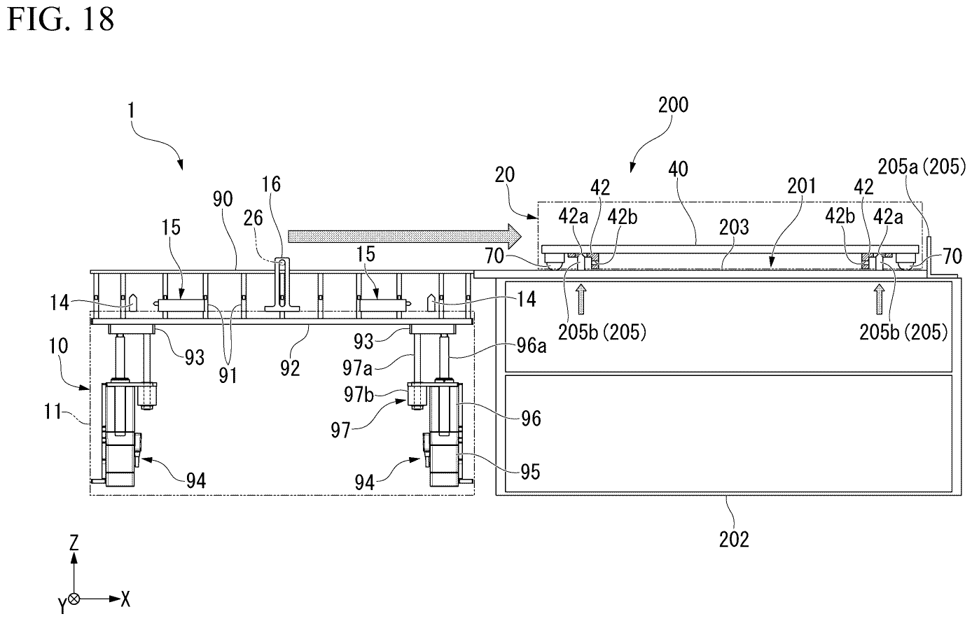

The stopper 205a is, for example, a plate member formed in an L shape, disposed between the pair of connecting rails 203, and capable of coming into contact with the performance board unit 20 in the X-axis direction. The stopper 205a, together with a fixing pin 205b (see FIG. 18) to be described later, forms a fixing mechanism 205 that fixes the performance board unit 20 that has been transferred from the caster rail 90 to the connecting rail 203.

As illustrated in FIG. 15, the connecting rail 203 has a connecting groove 203c to which an end part of the caster rail 90 can be connected in the X-axis direction. The connecting rail 203 has a width in the Y-axis direction greater than that of the caster rail 90, and the caster rail 90 is connected to the connecting rail 203 by being inserted into the connecting groove 203c.

The caster rail 90 includes a rolling path 90a along which the caster 70 rolls, and a pair of restriction walls 90b erected on both sides of the rolling path 90a to restrict derailment of the caster 70. The connecting rail 203 includes a rolling path 203a that is continuous with the rolling path 90a, and a pair of restriction walls 203b that are continuous with the pair of restriction walls 90b. Thereby, the performance board unit 20 can be safely transferred from the caster rail 90 to the connecting rail 203 while preventing derailment of the caster 70.

After the connecting rail 203 of the jig 201 is connected to the caster rail 90, the target covers (the first side cover 21b and the second side cover 21c on the −Y side) of the performance board unit 20 are removed as illustrated in FIG. 8. Then, the external connector (not illustrated) is pulled out from the connector portion 72 (step S4).

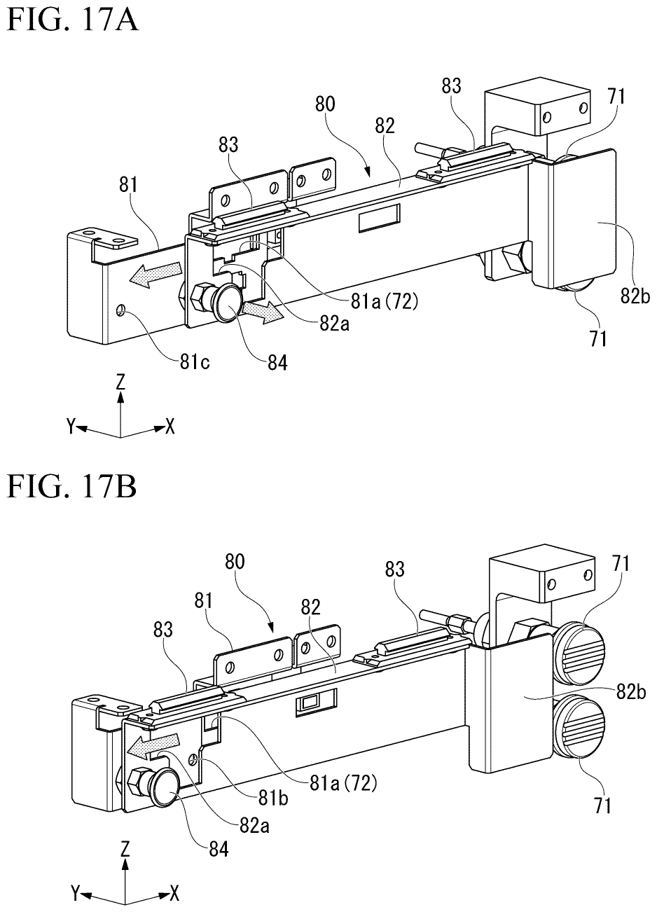

FIGS. 17A and 17B is an explanatory view for explaining step S5 shown in FIG. 11.

After the external connector (not illustrated) is pulled out from the connector portion 72, the interlock portion 80 is operated as illustrated in FIGS. 17A and 17B. The interlock portion 80 is a safety device that enables operation of the operation unit 71 after the connection at the connector portion 72 has been released. Thereby, sliding of the performance board unit 20 can be prevented while the external connector is connected.

As illustrated in FIG. 17A, the interlock portion 80 includes a first plate 81 and a second plate 82 that is slidable in the X-axis direction relative to the first plate 81. A first opening 81a through which the connector portion 72 is exposed is formed in the first plate 81. A second opening 82a that is allowed to communicate with the first opening 81a in the Y-axis direction is formed in the second plate 82. A slide piece 83 is attached to an upper part of the second plate 82. The slide piece 83 is engaged with a rail member, which has a dovetail groove-shaped slide groove (not illustrated) extending in the X-axis direction, to be movable in the X-axis direction.

The second plate 82 is movable between a communication position in which the second opening 82a communicates with the first opening 81a as illustrated in FIG. 17A, and a non-communication position in which the second opening 82a does not communicate with the first opening 81a as illustrated in FIG. 17B. The second plate 82 includes a cover portion 82c that covers the operation unit 71 when the second plate 82 is positioned at the communication position illustrated in FIG. 17A and exposes the operation unit 71 when the second plate 82 is positioned at the non-communication position illustrated in FIG. 17B.

Also, a plunger 84 is provided on the second plate 82. A first plunger hole 81b and a second plunger hole 81c are formed in the first plate 81. The first plunger hole 81b engages with the plunger 84 when the second plate 82 is at the communication position illustrated in FIG. 17A. Also, the second plunger hole 81c engages with the plunger 84 when the second plate 82 is at the non-communication position illustrated in FIG. 17B.

In step S5, after the external connector (not illustrated) is pulled out from the connector portion 72, the plunger 84 is pulled to release the engagement with the first plunger hole 81b. Then, the second plate 82 is moved from the communication position illustrated in FIG. 17A to the non-communication position illustrated in FIG. 17B. When the second plate 82 moves to the non-communication position, the plunger 84 engages with the second plunger hole 81c by a built-in spring. Also, when the second plate 82 moves to the non-communication position, the cover portion 82c shifts away from the front of the operation unit 71, thereby exposing the two operation units 71.

In step S6, the spring pins of the two lock plungers 26 illustrated in FIG. 7 are retracted by pulling the two operation units 71. Thereby, the engagement between the lock plunger 26 and the lock bracket 16 can be released.

FIG. 18 is an explanatory view for explaining steps S7 and S8 shown in FIG. 11.

After the engagement between the lock plunger 26 and the lock bracket 16 is released, the performance board unit 20 is slid in the X-axis direction along the caster rail 90 as illustrated in FIG. 18. Then, the performance board unit 20 is transferred from the caster rail 90 onto the connecting rail 203 of the jig 201.

After the performance board unit 20 is slid to a position at which it comes into contact with or is close to the stopper 205a, the fixing pin 205b is inserted into the positioning hole 42a of the engagement piece 42. Thereby, the performance board unit 20 that has been transferred from the caster rail 90 to the connecting rail 203 can be fixed. Further, the fixing pins 205b may be individually inserted by an operator, or may be mechanically inserted by pulling a lever (not illustrated), or may be electrically inserted by pressing a button (not illustrated).

In this way, when the performance board unit 20 is removed, the accommodating portion 12 (see FIG. 3) of the main body unit 10 is opened, and the board units 30 can be easily replaced according to specifications of the semiconductor circuit formed on the wafer W. Also, exchange of the removed performance board unit 20 can be easily performed. Although the performance board unit 20 is a heavy object, as described above, it can be easily attached and detached because it is slidable by the caster 70 and the caster rail 90.

As described above, the tester 1 according to the present embodiment includes the performance board unit 20 on which the probe card 3 for testing a semiconductor circuit is mounted, and the main body unit 10 to which the performance board unit 20 is detachably attached, in which the performance board unit 20 has the caster 70 on a side closer to the main body unit 10, and the main body unit 10 has the caster rail 90 supporting the caster 70 and the lifting unit 94 that raises and lowers the caster rail 90 in an attachment/detachment direction of the performance board unit 20. According to this configuration, the tester 1 in which attachment and detachment of the performance board unit 20, which is a heavy object, is facilitated is obtained.

Also, in the present embodiment, the main body unit 10 includes the lock bracket 16 having a long hole extending in the attachment/detachment direction, and the performance board unit 20 includes the lock plunger 26 that engages with the long hole of the lock bracket 16 to be movable in the attachment/detachment direction and restricts movement of the performance board unit 20 along the caster rail 90. With this configuration, even if the caster rail 90 is raised and the positioning pin 14 is pulled out from the positioning hole 42a of the engagement piece 42, since the lock plunger 26 engages with an upper end part of the long hole of the lock bracket 16, movement of the performance board unit 20 along the caster rail 90 can be restricted. Thereby, the performance board unit 20, which is a heavy object, can be prevented from unintentionally moving due to vibration or its own weight when the caster rail 90 is raised.

Also, in the present embodiment, the performance board unit 20 includes the connector portion 72 that is connected to the main body unit 10 in a direction other than the attachment/detachment direction, the operation unit 71 that releases engagement of the lock plunger 26 with the lock bracket 16, and the interlock portion 80 that enables operation of the operation unit 71 when the connection of the connector portion 72 is released. According to this configuration, removal of the performance board unit 20 with the external connector connected to the connector portion 72 can be prevented.

Also, in the present embodiment, the main body unit 10 includes the plurality of board units 30 having the plurality of first connectors 31, and the performance board unit 20 includes the plurality of second connectors 41 connected to the plurality of first connectors 31 in the attachment/detachment direction, the plurality of lock levers 41a provided in the plurality of second connectors 41 and movable between a fixed position in which the plurality of second connectors 41 and the plurality of first connectors 31 are fixed and a released position in which the fixation between the plurality of second connectors 41 and the plurality of first connectors 31 is released, the lock lever interlocking mechanism 52 moving the plurality of lock levers 41a between the fixed position and the released position, and the motor unit 51 receiving power supply from the main body unit 10 via the connector portion 72 to operate the lock lever interlocking mechanism 52. According to this configuration, connector connection and connector disconnection when the performance board unit 20 is attached to or detached from the main body unit 10 can be performed within a short period of time.

Also, the attachment/detachment system 200 of the performance board unit 20 of the present embodiment includes the tester 1 and the jig 201 that has the connecting rail 203 that can be connected to the caster rail 90 in a raised state by the lifting unit 94. According to this configuration, when the performance board unit 20 is transferred from the caster rail 90 onto the connecting rail 203 of the jig 201, replacement of the board unit 30 or exchange of the performance board unit 20 can be easily performed.

Also, in the present embodiment, the jig 201 includes the fixing mechanism 205 that fixes the performance board unit 20 that has been transferred from the caster rail 90 to the connecting rail 203. According to this configuration, the performance board unit 20 can be safely transported by being placed on the jig 201.

Also, an attachment/detachment method for the performance board unit 20 of the present embodiment is an attachment/detachment method for the performance board unit 20 of the tester 1 including the performance board unit 20 on which the probe card 3 for testing a semiconductor circuit is mounted, and the main body unit 10 to which the performance board unit 20 is detachably attached, and includes providing the caster 70 on a side closer to the main body unit 10 of the performance board unit 20, providing the main body unit 10 with the caster rail 90 supporting the caster 70 and the lifting unit 94 raising and lowering the caster rail 90 in the attachment/detachment direction of the performance board unit 20, and sliding the performance board unit 20 along the caster rail 90 after the caster rail 90 is raised by the lifting unit 94. According to this configuration, the performance board unit 20, which is a heavy object, can be easily attached and detached.

Also, in the present embodiment, in the above-described attachment/detachment method, the jig 201 having the connecting rail 203 that can be connected to the caster rail 90 is placed adjacent to the tester 1, the caster rail 90 that is in a raised state by the lifting unit 94 is connected to the connecting rail 203, and at least a part of the performance board unit 20 is transferred from the caster rail 90 to the connecting rail 203. According to this configuration, when the performance board unit 20 is transferred from the caster rail 90 to the connecting rail 203 of the jig 201, it becomes easy to replace the board unit 30 or exchange the performance board unit 20. Further, when only replacement of the board unit 30 is performed, it is not necessary to completely transfer the performance board unit 20 onto the jig 201.

While preferred embodiments of the present invention have been described and illustrated, it should be understood that they are exemplary of the present invention and are not to be considered as limiting. Additions, omissions, substitutions, and other modifications can be made without departing from the scope of the present invention. Accordingly, the present invention is not to be considered as being limited by the foregoing description and is only limited by the scope of the claims.

For example, in the above-described embodiment, the jig 201 is disposed on a side of the tester 1, and the performance board unit 20 is transferred from the caster rail 90 onto the connecting rail 203 of the jig 201, but the present invention is not limited to this configuration. The performance board unit 20 may also be slid onto a member other than the jig 201 (for example, an upper surface or the like of a work table). Also, if the performance board unit 20 can be slid within a range of the caster rail 90, at least a part of the accommodating portion 12 of the main body unit 10 can be opened, and therefore the performance board unit 20 does not need to be transferred onto the jig 201 or another member other than the jig 201.

For example, in the above-described embodiment, the probe card 3 has been exemplified as the device under test, but the present invention is not limited to this configuration. For example, if the tester 1 is used as a handler that dices semiconductor circuits from the wafer W into chips, packages them, and then inspects them by placing them on a test socket, the test socket may serve as the device under test.

In addition, the components in the above-described embodiments can be appropriately replaced with well-known components within a range not departing from the spirit of the present invention, and the above-described embodiments and modified examples may be appropriately combined.

What is claimed is:

1. A semiconductor testing device comprising:
a signal transmission unit on which a device under test for testing a semiconductor circuit is mounted; and
a main body unit to which the signal transmission unit is detachably attached, wherein
the signal transmission unit includes a caster on a side closer to a main body unit, and
the main body unit includes:
a caster rail supporting the caster; and
a lifting unit raising and lowering the caster rail in an attachment/detachment direction of the signal transmission unit.

2. The semiconductor testing device according to claim 1, wherein
the main body unit includes a lock bracket having a long hole extending in the attachment/detachment direction, and
the signal transmission unit includes a lock plunger engaging with the long hole of the lock bracket to be movable in the attachment/detachment direction and restricting movement of the signal transmission unit along the caster rail.

3. The semiconductor testing device according to claim 2, wherein the signal transmission unit includes:
a connector portion connected to the main body unit in a direction other than the attachment/detachment direction;
an operation unit releasing engagement of the lock plunger with the lock bracket; and
an interlock portion enabling operation of the operation unit when a connection of the connector portion is released.

4. The semiconductor testing device according to claim 3, wherein
the main body unit includes a plurality of board units having a plurality of first connectors, and
the signal transmission unit includes:
a plurality of second connectors connected to the plurality of first connectors in the attachment/detachment direction;
a plurality of lock levers provided in the plurality of second connectors and movable between a fixed position in which the plurality of second connectors and the plurality of first connectors are fixed and a released position in which a fixation between the plurality of second connectors and the plurality of first connectors is released;
a lock lever interlocking mechanism moving the plurality of lock levers between the fixed position and the released position; and
a motor unit receiving power supply from the main body unit via the connector portion to operate the lock lever interlocking mechanism.

5. An attachment/detachment system for a signal transmission unit comprising:
the semiconductor testing device according to claim 1; and
a jig including a connecting rail connectable to the caster rail when brought into a raised state by the lifting unit.

6. The attachment/detachment system for a signal transmission unit according to claim 5, wherein
the jig includes a fixing mechanism fixing the signal transmission unit which has been transferred from the caster rail to the connecting rail.

7. An attachment/detachment method for a signal transmission unit, which is an attachment/detachment method for the signal transmission unit of a semiconductor testing device including the signal transmission unit on which a device under test for testing a semiconductor circuit is mounted, and a main body unit to which the signal transmission unit is detachably attached, the attachment/detachment method comprising:
providing a caster on a side closer to the main body unit of the signal transmission unit;
providing the main body unit with a caster rail supporting the caster and a lifting unit raising and lowering the caster rail in an attachment/detachment direction of the signal transmission unit; and
sliding the signal transmission unit along the caster rail after the caster rail is raised by the lifting unit.

8. The attachment/detachment method for the signal transmission unit according to claim 7, wherein
a jig having a connecting rail connectable to the caster rail is placed adjacent to the semiconductor testing device,
the caster rail which is in a raised state by the lifting unit is connected to the connecting rail, and
at least a part of the signal transmission unit is transferred from the caster rail to the connecting rail.
